(19) United States
(12) Patent Application Publication
(10) Pub. No.: US 2026/0106595 A1
(43) Pub. Date: Apr. 16, 2026

(54) RESONATOR AND PREPARATION METHOD THEREFOR

(71) Applicant: WUHAN MEMSONICS TECHNOLOGIES CO LTD, Donghu New Tech. Development Zone Wuhan (CN)

(72) Inventors: Jinzhao HAN, Donghu New Tech. Development Zone Wuhan (CN); Yao CAI, Donghu New Tech. Development Zone Wuhan (CN); Jinhao DAI, Donghu New Tech. Development Zone Wuhan (CN); Bowoon SOON, Donghu New Tech. Development Zone Wuhan (CN); Chengliang SUN, Donghu New Tech. Development Zone Wuhan (CN); Shishang GUO, Donghu New Tech. Development Zone Wuhan (CN)

(21) Appl. No.: 19/314,929

(22) Filed: Aug. 29, 2025

Related U.S. Application Data
(63) Continuation of application No. PCT/CN2025/079627, filed on Feb. 27, 2025.

(30) Foreign Application Priority Data
Oct. 12, 2024 (CN) 202411426075.6

(51) Int. Cl. H03H 9/05; H03H 3/02; H03H 3/04; H03H 9/02; H03H 9/17

(52) U.S. Cl. CPC H03H 9/0542; H03H 3/04; H03H 9/02086; H03H 9/173; H03H 2003/021; H03H 2003/0478

(57) ABSTRACT

The present disclosure provides a resonator and a preparation method therefor, relating to the technical field of resonators. The resonator comprises a substrate, and a first electrode layer, a first piezoelectric layer, and a second electrode layer which are sequentially stacked onto the substrate. The first electrode layer, the first piezoelectric layer, and the second electrode layer form a first overlapping region along the stacking direction. A capacitor stacking layer is arranged on the first piezoelectric layer and located outside the first overlapping region. A passivation layer is arranged above the second electrode layer, and the passivation layer extends above the capacitor stacking layer.

### CROSS-REFERENCE TO RELATED APPLICATIONS

This application is a continuation of PCT International Application No. PCT/CN2025/079627 filed on Feb. 27, 2025. This application claims the priority to the Chinese patent application No. 2024114260756 filed with the Chinese Patent Office on Oct. 12, 2024, entitled “RESONATOR AND PREPARATION METHOD THEREFOR”, the contents of which are incorporated herein by reference in entirety.

### TECHNICAL FIELD

The present disclosure relates to the technical field of resonators, and specifically, relates to a resonator and a preparation method therefor.

### BACKGROUND ART

With the rapid development of wireless communication technology, more and more devices are used for transmitting and receiving information at higher frequency bands, and the requirements for radio frequency front-end circuits are becoming increasingly stringent, so the market demand for high-performance filters is growing increasingly. Bulk acoustic wave filters are gradually becoming the mainstream in the market due to characteristics such as high quality factor, good out-of-band suppression, and high rectangular coefficient.

Bulk acoustic wave filters are formed by arranging a plurality of resonators in cascade according to a specific circuit. High-performance filters require high-performance resonators. High-performance resonators provide a high-quality factor. High quality factor enables the filter to provide smaller insertion loss and steeper roll-off characteristics, and to provide superior filtering performance. In summary, it is very important to prepare resonators with high stability and excellent performance.

### SUMMARY

The objective of the present disclosure is to address the deficiencies in the prior art and provide a resonator and a preparation method therefor.

In order to achieve the above objective, the technical solution adopted in the embodiments of the present disclosure is as follows.

In one aspect of the embodiments of the present disclosure, a resonator is provided, comprising a substrate, and a first electrode layer, a first piezoelectric layer, and a second electrode layer which are sequentially stacked onto the substrate. The first electrode layer, the first piezoelectric layer, and the second electrode layer form a first overlapping region along the stacking direction. A capacitor stacking layer is arranged on the first piezoelectric layer and located outside the first overlapping region. A passivation layer is arranged above the second electrode layer, and the passivation layer extends above the capacitor stacking layer.

Optionally, the capacitor stacking layer comprises a lower electrode, a dielectric layer, and an upper electrode which are sequentially stacked onto the first piezoelectric layer. The resonator further comprises a first lead-out portion and a second lead-out portion. The first lead-out portion penetrates the passivation layer and contacts the lower electrode. The second lead-out portion penetrates the passivation layer and contacts the upper electrode. The first lead-out portion and the second lead-out portion do not overlap along the stacking direction.

Optionally, the lower electrode and the upper electrode have a second overlapping region along the stacking direction, and the first lead-out portion and the second lead-out portion are both located outside the second overlapping region.

Optionally, the capacitor stacking layer comprises a plurality of upper electrodes, and a lower electrode and a dielectric layer which are sequentially stacked onto the first piezoelectric layer. The plurality of upper electrodes are arranged on one side of the dielectric layer away from the lower electrode, and the plurality of upper electrodes are arranged at intervals at intervals. The plurality of upper electrodes cooperate with the lower electrode to form a plurality of capacitors.

Optionally, the resonator further comprises a third lead-out portion and a plurality of fourth lead-out portions. The third lead-out portion penetrates the passivation layer and contacts the lower electrode. The plurality of fourth lead-out portions respectively penetrates the passivation layer and contact the plurality of upper electrodes one-to-one.

Optionally, the resonator further comprises a plurality of fourth lead-out portions. The plurality of fourth lead-out portions respectively penetrates the passivation layer and contact the plurality of upper electrodes one-to-one.

Optionally, an insulating layer is arranged between the first piezoelectric layer and the capacitor stacking layer.

Optionally, a mass loading layer located in the first overlapping region is arranged between the first piezoelectric layer and the second electrode layer.

Optionally, a second piezoelectric layer is arranged between the substrate and the first electrode layer.

Optionally, a first cavity and a second cavity are further arranged between the substrate and the first piezoelectric layer. The first cavity is at least partially located within the first overlapping region, and the second cavity is located directly below the capacitor stacking layer.

Optionally, an oxide layer is filled within the second cavity.

In another aspect of the embodiments of the present disclosure, a preparation method for a resonator is provided, comprising:
sequentially forming a stacked second piezoelectric layer, a first electrode layer, and a first piezoelectric layer on a substrate;
forming a mass loading layer on the first piezoelectric layer;
forming a second electrode layer on the mass loading layer and forming a lower electrode on the first piezoelectric layer, wherein the second electrode layer and the lower electrode are arranged at intervals;
forming a dielectric layer on the lower electrode;
forming at least one upper electrode on the dielectric layer, wherein the lower electrode, the dielectric layer, and the at least one upper electrode form a capacitor stacking layer; and forming a passivation layer on the second electrode layer, wherein the passivation layer extends above the capacitor stacking layer.

### BRIEF DESCRIPTION OF DRAWINGS

To more clearly illustrate the technical solutions of the embodiments of the present disclosure, the following will briefly introduce the drawings used in the embodiments. It should be understood that the following drawings only show some embodiments of the present disclosure, and therefore they should not be regarded as a limitation on the scope. Those ordinarily skilled in the art can also obtain other related drawings based on these drawings without inventive effort.

FIG. 1 is a schematic diagram of a state of a preparation method for a resonator provided in the embodiments of the present disclosure;

FIG. 2 is another schematic diagram of a state of a preparation method for a resonator provided in the embodiments of the present disclosure;

FIG. 3 is another schematic diagram of a state of a preparation method for a resonator provided in the embodiments of the present disclosure;

FIG. 4 is another schematic diagram of a state of a preparation method for a resonator provided in the embodiments of the present disclosure;

FIG. 5 is another schematic diagram of a state of a preparation method for a resonator provided in the embodiments of the present disclosure;

FIG. 6 is another schematic diagram of a state of a preparation method for a resonator provided in the embodiments of the present disclosure;

FIG. 7 is another schematic diagram of a state of a preparation method for a resonator provided in the embodiments of the present disclosure;

FIG. 8 is a structural schematic diagram of a resonator provided in the embodiments of the present disclosure;

FIG. 9 is another structural schematic diagram of a resonator provided in the embodiments of the present disclosure;

FIG. 10 is another structural schematic diagram of a resonator provided in the embodiments of the present disclosure;

FIG. 11 is another structural schematic diagram of a resonator provided in the embodiments of the present disclosure;

FIG. 12 is another structural schematic diagram of a resonator provided in the embodiments of the present disclosure; and

FIG. 13 is another structural schematic diagram of a resonator provided in the embodiments of the present disclosure.

### DETAILED DESCRIPTION OF EMBODIMENTS

In order to make the objective, technical solutions, and advantages of the embodiments of the present disclosure clearer, the following description will provide a clear and comprehensive explanation of the technical solutions in the embodiments of the present disclosure with reference to the drawings of the present disclosure. Clearly, the described embodiments are part of the embodiments of the present disclosure and not the entire embodiments. The components of embodiments of the present disclosure which are generally described and illustrated in the drawings herein can be arranged and designed in a variety of different configurations.

Accordingly, the following detailed description of the embodiments of the present disclosure provided in the drawings is not intended to limit the scope of the present disclosure for which protection is claimed, but merely represents selected embodiments of the present disclosure. It should be noted that, without conflicts, various features in the embodiments of the present disclosure can be combined with each other, and the combined embodiments still fall within the protection scope of the present disclosure.

It should be noted that similar numerals and letters denote similar terms in the following drawings so that once an item is defined in one drawing, it does not need to be further discussed in subsequent drawings.

In the description of the present disclosure, it should be noted that the orientation or positional relationship indicated by the term s “center”, “up”, “down”, “left”, “right”, “vertical”, “horizontal”, “inside”, “outside”, etc., is based on the orientation or positional relationship shown in the drawings or the orientation or positional relationship in which the product of the present disclosure is customarily placed when used. It is intended only to facilitate the description of the present disclosure and to simplify the description, and not to indicate or imply that the devices or elements referred to must have a particular orientation, be constructed and operated in a particular orientation. Accordingly, it is not to be construed as a limitation of the present disclosure. In addition, the terms “first”, “second”, and “third” are only used to distinguish the descriptive and are not to be construed as indicating or implying relative importance.

In addition, the terms such as “horizontal”, “vertical” do not mean that components are required to be absolutely horizontal or overhanging, but can be slightly inclined. For example, “horizontal” only means that its direction is more horizontal than “vertical”, and it does not mean that the structure must be completely horizontal, but can be slightly inclined.

In the description of the present disclosure, it further needs to be noted that unless otherwise clearly stipulated and limited, the terms “provide”, “mount”, “”, and “connect” should be understood in a broad sense, for example, it can be a fixed connection, a detachable connection, or an integral connection; it can be a mechanical connection, or an electrical connection; and it can be a direct connection, an indirect connection through an intermediary, or an internal communication between two components. Those of ordinary skill in the art can understand the specific meanings of the above terms in the present disclosure according to specific situations.

In one aspect of the embodiments of the present disclosure, a resonator is provided. Referring to any one of FIG. 8 to FIG. 13, the resonator comprises a substrate 101 and a piezoelectric stacking layer provided on the substrate 101, wherein the piezoelectric stacking layer comprises a first electrode layer 104, a first piezoelectric layer 105, and a second electrode layer 109 which are sequentially stacked onto the substrate 101, so as to facilitate the mutual conversion between electrical energy and mechanical energy by means of the first piezoelectric layer 105 after applying an electrical signal to the first electrode layer 104 and the second electrode layer 109. It should be understood that the stacking direction in the present disclosure is the vertical direction in any one of FIG. 8 to FIG. 13, or in other words, the thickness direction of the substrate 101.

Continuing to refer to any one of FIG. 8 to FIG. 13, the first electrode layer 104, the first piezoelectric layer 105, and the second electrode layer 109 form a first overlapping region along the stacking direction. Generally, the first overlapping region is also used as an effective resonant region or effective working region of the resonator.

In order to optimize the performance of the resonator, as shown in any one of FIG. 8 to FIG. 13, a capacitor stacking layer 114 is arranged on the first piezoelectric layer 105. In this way, capacitors can be integrated inside the resonator, thereby realizing on-chip directly integrated capacitors. Compared with external capacitors, the capacitor occupies smaller area and does not require additional lead-out routing, which avoids corresponding electrical parasitic effects, thereby improving the performance of the resonator and the filter.

When integrating the capacitor stacking layer 114, the capacitor stacking layer 114 and the first overlapping region can be arranged to be as independent as possible from each other. Therefore, the capacitor stacking layer 114 can be located outside the first overlapping region. For example, there is no first electrode layer 104 directly below the capacitor stacking layer 114. In other words, the capacitor stacking layer 114 and the first electrode layer 104 do not intersect in the stacking direction. This enables the on-chip integrated capacitor stacking layer 114 not to affect the first overlapping region of the resonator.

On this basis, as shown in any one of FIG. 8 to FIG. 13, a passivation layer 115 can be arranged above the entire device (on the side away from the substrate 101), so as to provide passivation protection for other basic layers of the resonator. Specifically, the passivation layer 115 can be located above the second electrode layer 109, and the passivation layer 115 also extends above the capacitor stacking layer 114 and the first piezoelectric layer 105. It should be specifically noted that in the present disclosure, the passivation layer 115 and the capacitor stacking layer 114 are independent of each other. Therefore, the material thickness of the dielectric layer 112 inside the capacitor stacking layer 114 is not limited by the passivation requirement of the device. Thus, the material thickness of the dielectric layer 112 inside the capacitor stacking layer 114 can be optimized based on performance, and can also be flexibly varied according to demand.

The above-mentioned capacitor stacking layer 114 should refer to a structure capable of exhibiting capacitive characteristics. The specific structure thereof can be reasonably selected and arranged according to actual needs. Certainly, for ease of understanding, the present disclosure will describe some examples in conjunction with the drawings.

Referring to FIG. 8, the capacitor stacking layer 114 is located outside the first overlapping region, and specifically can be located on the right side of the first overlapping region. The capacitor stacking layer 114 comprises a lower electrode 111, a dielectric layer 112, and an upper electrode 113, wherein the lower electrode 111 is located on the upper surface of the first piezoelectric layer 105, the dielectric layer 112 is located above the lower electrode 111, and the upper electrode 113 is located above the dielectric layer 112. Thereby, a single capacitor structure is formed through the lower electrode 111, the dielectric layer 112, and the upper electrode 113.

In order to smoothly lead out the lower electrode 111 and the upper electrode 113 of the capacitor stacking layer 114. Continuing to refer to FIG. 8, the resonator further comprises a first lead-out portion 116 and a second lead-out portion 117, wherein the first lead-out portion 116 penetrates the passivation layer 115 and contacts the lower electrode 111, and the second lead-out portion 117 penetrates the passivation layer 115 and contacts the upper electrode 113. In this way, the capacitor stacking structure can be connected into a circuit through the first lead-out portion 116 and the second lead-out portion 117. Moreover, the first lead-out portion 116 and the second lead-out portion 117 do not overlap in the stacking direction. In other words, the portion where the lower electrode 111 contacts the first lead-out portion 116 and the portion where the upper electrode 113 contacts the second lead-out portion 117 are offset in the stacking direction so as to form a non-overlapping state. This facilitates the lead-out of the upper electrode 113 and the lower electrode 111.

The lower electrode 111 and the upper electrode 113 of the capacitor stacking layer 114 form a second overlapping region in the stacking direction to satisfy the capacitor arrangement requirement. On this basis, the performance of the capacitor stacking layer 114 can be optimized. For example, both the first lead-out portion 116 and the second lead-out portion 117 are both located outside the second overlapping region, which can prevent the first lead-out portion 116 from directly facing the upper electrode 113 and also prevent the second lead-out portion 117 from directly facing the lower electrode 111, thereby preventing the potential parasitic capacitor between the first lead-out portion 116 and the upper electrode 113, and the same applies between the second lead-out portion 117 and the lower electrode 111.

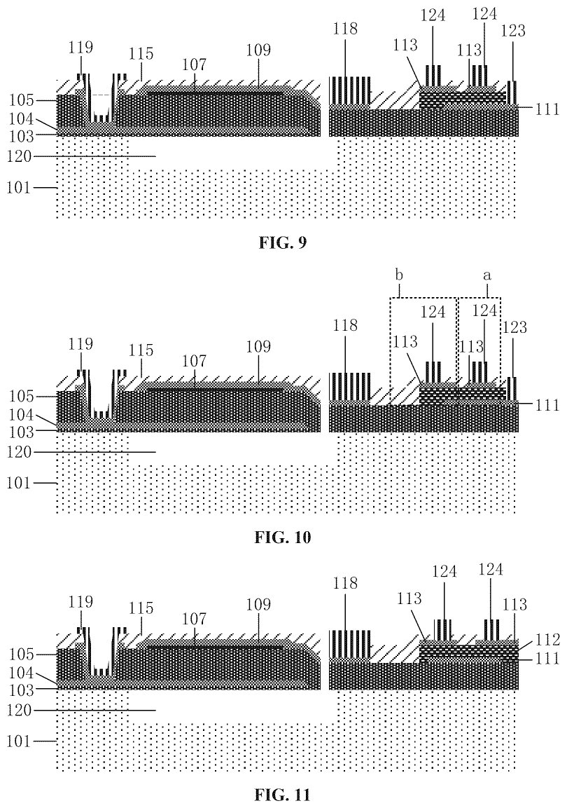

Referring to FIG. 9 or FIG. 11, the capacitor stacking layer 114 is located outside the first overlapping region, and specifically can be located on the right side of the first overlapping region. The capacitor stacking layer 114 includes the lower electrode 111, a dielectric layer 112, and a plurality of upper electrodes 113. The lower electrode 111 is stacked onto the first piezoelectric layer 105, the dielectric layer 112 is stacked onto the lower electrode 111, and the plurality of upper electrodes 113 are laid on the surface of the dielectric layer 112 away from the lower electrode 111. The plurality of upper electrodes 113 are arranged at intervals in pairs. Each upper electrode 113 has a portion directly facing the lower electrode 111, so that one upper electrode 113 can cooperate with the lower electrode 111 to form a capacitor. Likewise, the plurality of upper electrodes 113 can cooperate with the lower electrode 111 respectively to form a plurality of capacitors. Specifically, as shown in FIG. 9 or FIG. 11, the capacitor stacking layer 114 includes one lower electrode 111, one dielectric layer 112, and two upper electrodes 113. The lower electrode 111 is stacked onto the first piezoelectric layer 105, the dielectric layer 112 is stacked onto the lower electrode 111, and the two upper electrodes 113 are laid on the dielectric layer 112 and spaced apart left and right. The left upper electrode 113 cooperates with the lower electrode 111 to form a capacitor, and the right upper electrode 113 cooperates with the lower electrode 111 to form another capacitor.

To meet different capacitor connection requirements, the lower electrode 111 can be selectively led out or not led out, as will be described below with reference to the drawings.

For example, as shown in FIG. 9, the lower electrode 111 can be led out. Specifically, the resonator further comprises a third lead-out portion 123 and a plurality of fourth lead-out portions 124. The third lead-out portion 123 penetrates the passivation layer 115 and contacts the lower electrode 111. The plurality of fourth lead-out portions 124 respectively penetrate the passivation layer 115 and contact the plurality of upper electrodes 113 one-to-one. Thus, the lower electrode 111 can be led out through the third lead-out portion 123, and each upper electrode 113 can be led out through one fourth lead-out portion 124. In this way, when the capacitor stacking layer 114 is connected into a circuit, the lower electrode 111 and at least a portion of the upper electrodes 113 can be flexibly connected as needed. For example, when one capacitor is needed, the lower electrode 111 and one upper electrode 113 can be connected; when two capacitors are needed, the lower electrode 111 and two upper electrodes 113 can both be connected into the circuit. It should also be understood that when the lower electrode 111 is also led out, the capacitors connected into the circuit can be configured in various connection forms such as series or parallel.

Alternatively, as shown in FIG. 11, the lower electrode 111 may not be led out. Specifically, the resonator further includes a plurality of fourth lead-out portions 124, wherein the plurality of fourth lead-out portions 124 respectively penetrate the passivation layer 115 and respectively contact the plurality of upper electrodes 113 one-to-one. Thus, the lower electrode 111 may not be led out, and each upper electrode 113 can be led out through one fourth lead-out portion 124. In this way, when the capacitor stacking layer 114 is connected into the circuit, the two capacitors therein can form a series connection via the lower electrode 111. For example, in FIG. 11, the left upper electrode 113 and the lower electrode 111 form one capacitor, and the right upper electrode 113 and the lower electrode 111 form another capacitor. During circuit connection, the two capacitors can be connected into the circuit only through the two fourth lead-out portions 124, thereby allowing the two capacitors to be connected in series.

When the capacitor stacking layer 114 is capable of forming a plurality of capacitors, series or parallel connections among different capacitors can be adjusted through external leads, so as to adjust the capacitor value and meet the requirements of capacitor precision in the preparation process. For example, as shown in FIG. 10, two capacitors are shown, wherein the right-side capacitor can be taken as main capacitor a, and the left-side capacitor can be taken as auxiliary capacitor b. In order to meet the requirement of capacitor precision in the preparation process, in the subsequent packaging test, if the precision of the main capacitor a does not meet the requirement, the series or parallel connection of the main capacitor a and the auxiliary capacitor b is realized through the connection of external leads at this time, thereby adjusting the capacitor value.

The capacitor value of the auxiliary capacitor is 10-30% of the capacitor value of the main capacitor, so that the adjustment range of the capacitor value is more likely to meet actual requirements.

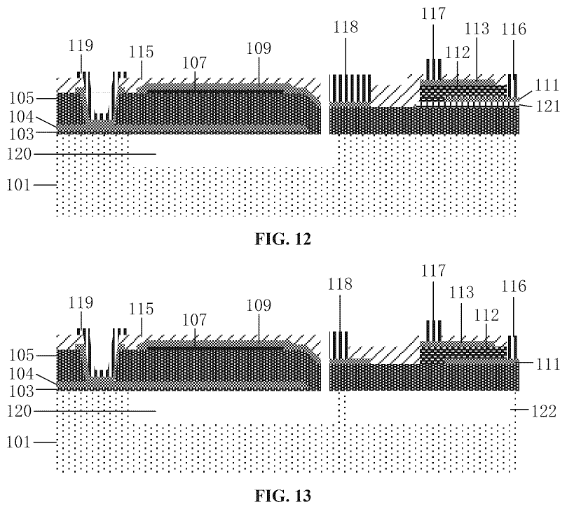

In some possible embodiments, an insulating layer 121 is arranged between the first piezoelectric layer 105 and the capacitor stacking layer 114, so that the capacitor stacking layer 114 can be isolated through the insulating layer 121, thereby improving the performance of the capacitor stacking layer 114. For example, in FIG. 12, an insulating layer 121 is arranged between the first piezoelectric layer 105 and the capacitor stacking layer 114. It should be understood that in any identical or similar resonator in FIGS. 9 to 11, the insulating layer 121 can be arranged between the first piezoelectric layer 105 and the capacitor stacking layer 114, so as to optimize the performance of the resonator.

In some possible embodiments, as shown in FIGS. 8 to 13, a mass loading layer 107 located in the first overlapping region is arranged between the first piezoelectric layer 105 and the second electrode layer 109. The frequency of the resonator can be adjusted through the mass loading layer 107. Further, when the mass loading layer 107 is located between the first piezoelectric layer 105 and the second electrode layer 109, the material of the mass loading layer 107 can be the same as the material of the second electrode layer 109, thereby simplifying the preparation process.

In some possible embodiments, as shown in FIGS. 8 to 13, a second piezoelectric layer 103 is arranged between the substrate 101 and the first electrode layer 104. The second piezoelectric layer 103 can improve the formation quality of the subsequent first electrode layer 104.

In some possible embodiments, as shown in FIGS. 8 to 13, a first cavity 120 is also arranged between the substrate 101 and the first electrode layer 104, and the first cavity 120 is substantially located in the first overlapping region, so that acoustic waves in the first overlapping region can be reflected by the first cavity 120, thereby improving the performance of the resonator. It should be noted that when the first cavity 120 is also arranged between the substrate 101 and the first electrode layer 104, the first overlapping region is formed by the cavity, the first electrode layer 104, the first piezoelectric layer 105, and the second electrode layer 109 along the stacking direction.

In some possible embodiments, as shown in FIG. 13, a second cavity 122 is further arranged between the substrate 101 and the first piezoelectric layer 105. The second cavity 122 is located right below the capacitor stacking layer 114, so that the influence of the capacitor region formed by the substrate 101 and the capacitor stacking layer 114 can be isolated through the second cavity 122, thereby improving the performance of the capacitor formed by the capacitor stacking layer 114.

In some possible embodiments, an oxide layer is filled within the second cavity 122, so that the second cavity 122 can be filled through the oxide layer, and the supporting strength below the capacitor stacking layer 114 can be improved. In particular, for a multi-capacitor structure, the process stability can be improved.

In some possible embodiments, as shown in FIGS. 8 to 13, in order to facilitate the lead-out of the first electrode layer 104, a fifth lead-out portion 119 composed of a first metal layer 108 and a second metal layer 110 can also be provided. The fifth lead-out portion 119 passes through the passivation layer 115 and the first piezoelectric layer 105 and then contacts the first electrode layer 104. Similarly, in order to facilitate the lead-out of the second electrode layer 109, a sixth lead-out portion 118 formed by the second metal layer 110 can be provided. The sixth lead-out portion 118 passes through the passivation layer 115 and then contacts the second electrode layer 109 In another aspect of the embodiments of the present disclosure, a preparation method for a resonator is provided, comprising the following steps S10 to S60.

S10: sequentially forming a stacked second piezoelectric layer 103, a first electrode layer 104, and a first piezoelectric layer 105 on a substrate 101.

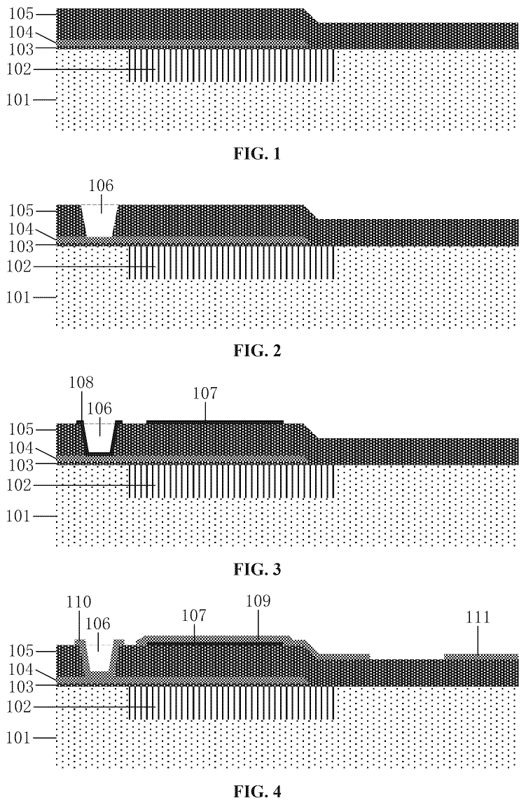

As shown in FIG. 1, after forming the second piezoelectric layer 103 on the substrate 101, a metal layer is deposited on the second piezoelectric layer 103, and after patterning the metal layer, a first electrode layer 104 is formed. Then, a first piezoelectric layer 105 is formed on the first electrode layer 104.

It can be understood that, when it is necessary to form the first cavity 120 and/or the second cavity 122, the first cavity 120 and/or the second cavity 122 can be formed on the substrate 101 through etching, and then a sacrificial layer 102 (oxide layer) is filled in the first cavity 120 and/or the second cavity 122, so that the surface of the substrate 101 is flattened, which facilitates the convenience of subsequent layers.

In order to facilitate the lead-out of the first electrode layer 104, the first piezoelectric layer 105 can be etched to form an electrode lead-out hole 106 penetrating through the first piezoelectric layer 105.

S20: forming a mass loading layer 107 on the first piezoelectric layer 105.

As shown in FIG. 2, a mass loading layer 107 is formed on the first piezoelectric layer 105 through deposition and patterning, and it is generally located in the first overlapping region. Correspondingly, to simplify the process, the mass loading layer 107 can be made of metal material, so that a whole metal layer is deposited and patterned to form the spaced mass loading layer 107 and the first metal layer 108 arranged at intervals, wherein the first metal layer 108 is located in the electrode lead-out hole 106.

S30: forming a second electrode layer 109 on the mass loading layer 107 and forming a lower electrode 111 on the first piezoelectric layer 105, wherein the second electrode layer 109 and the lower electrode 111 are arranged at intervals.

As shown in FIG. 3, a whole metal layer is deposited on the mass loading layer 107. After patterning, the second electrode layer 109, the lower electrode 111 on the first piezoelectric layer 105, and the second metal layer 110 on the first metal layer 108 are respectively formed, and the three are arranged at intervals from each other.

S40: forming a dielectric layer 112 on the lower electrode 111.

As shown in FIG. 4, a dielectric layer 112 is formed on the lower electrode 111, so as to facilitate the construction of the dielectric of the capacitor.

S50: forming at least one upper electrode 113 on the dielectric layer 112, wherein the lower electrode 111, the dielectric layer 112, and the at least one upper electrode 113 form a capacitor stacking layer 114.

As shown in FIG. 5, an upper electrode 113 is formed on the dielectric layer 112, wherein the lower electrode 111, the dielectric layer 112, and the upper electrode 113 form a capacitor stacking layer 114. Of course, when multiple capacitors need to be constructed, multiple upper electrodes 113 can be formed.

S60: forming a passivation layer 115 on the second electrode layer 109, wherein the passivation layer 115 extends above the capacitor stacking layer 114.

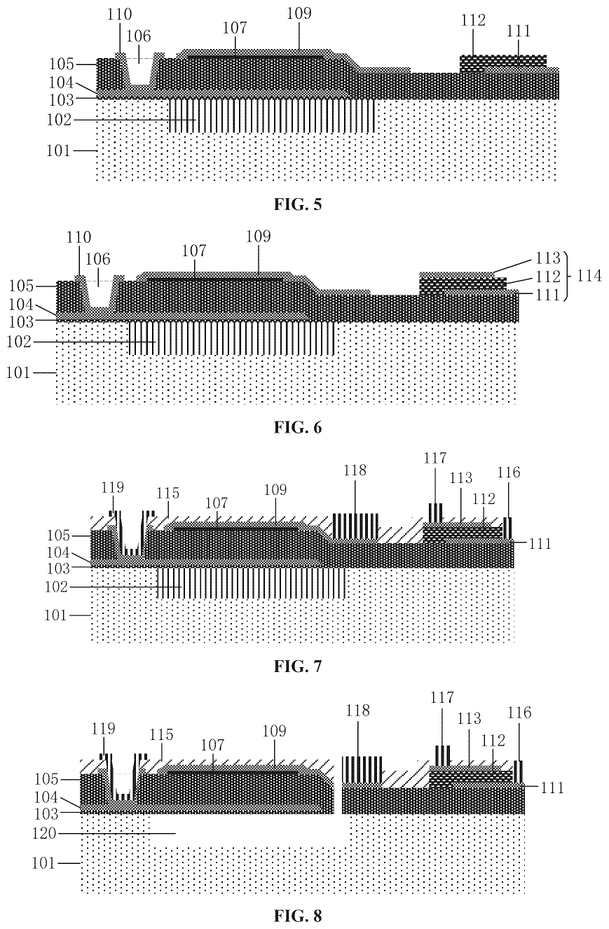

As shown in FIG. 6, a whole passivation layer 115 is deposited on the device shown in FIG. 5, so as to provide passivation protection. In order to facilitate the lead-out of the required electrodes, according to the requirements of the different aforementioned resonators, a first lead-out portion 116, a second lead-out portion 117, a third lead-out portion 123, a fourth lead-out portion 124, a fifth lead-out portion 119, and a sixth lead-out portion 118 are respectively provided.

As shown in FIG. 7, a release hole connected to the sacrificial layer 102 is finally formed, thereby forming the first cavity 120 and/or the second cavity 122.

It should be understood that the preparation method for the resonator can be used for preparing the aforementioned resonator.

The above is only a preferred embodiment of the present disclosure, which is not intended to limit, and the present disclosure may have various changes and variations for those skilled in the art. Any modification, equivalent substitution, improvement, etc., made within the spirit and principles of the present disclosure shall be included in the scope of protection of the present disclosure.

### INDUSTRIAL APPLICABILITY

The resonator and the preparation method therefor provided by the present disclosure are capable of achieving on-chip directly integrated capacitor, which, compared with an external capacitor, has a smaller occupied area, and does not require additionally introducing the lead-out routing to avoid corresponding electrical parasitic effects, thereby improving the performance of the resonator and the filter. Moreover, the passivation layer and the capacitor stacking layer are independent of each other. Therefore, the material thickness of the dielectric layer inside the capacitor stacking layer is not limited by the passivation requirement of the device. Thus, the material thickness of the dielectric layer inside the capacitor stacking layer can be preferably selected based on performance, and can also be flexibly varied according to demand. The capacitor value of the integrated capacitor can also be finely adjusted, so as to overcome the defect in process integration.

What is claimed is:

1. A resonator, comprising a substrate, and a first electrode layer, a first piezoelectric layer, and a second electrode layer which are sequentially stacked onto the substrate, wherein the first electrode layer, the first piezoelectric layer, and the second electrode layer form a first overlapping region along a stacking direction; a capacitor stacking layer is arranged on the first piezoelectric layer and located outside the first overlapping region; a passivation layer is arranged above the second electrode layer; and the passivation layer extends above the capacitor stacking layer.

2. The resonator according to claim 1, wherein the capacitor stacking layer comprises a lower electrode, a dielectric layer, and an upper electrode which are sequentially stacked onto the first piezoelectric layer;
the resonator further comprises a first lead-out portion and a second lead-out portion; the first lead-out portion penetrates the passivation layer and contacts the lower electrode; the second lead-out portion penetrates the passivation layer and contacts the upper electrode; and the first lead-out portion and the second lead-out portion do not overlap along the stacking direction.

3. The resonator according to claim 2, wherein the lower electrode and the upper electrode have a second overlapping region along the stacking direction, and the first lead-out portion and the second lead-out portion are both located outside the second overlapping region.

4. The resonator according to claim 1, wherein the capacitor stacking layer comprises a plurality of upper electrodes, and a lower electrode and a dielectric layer which are sequentially stacked onto the first piezoelectric layer; the plurality of upper electrodes are arranged on one side of the dielectric layer away from the lower electrode; the plurality of upper electrodes are arranged at intervals from each other; and the plurality of upper electrodes cooperate with the lower electrode to form a plurality of capacitors.

5. The resonator according to claim 4, wherein the resonator further comprises a third lead-out portion and a plurality of fourth lead-out portions; the third lead-out portion penetrates the passivation layer and contacts the lower electrode; the plurality of fourth lead-out portions respectively penetrates the passivation layer and contact the plurality of upper electrodes one-to-one.

6. The resonator according to claim 4, wherein the resonator further comprises a plurality of fourth lead-out portions, and the plurality of fourth lead-out portions respectively penetrate the passivation layer and contact the plurality of upper electrodes one-to-one.

7. The resonator according to claim 1, wherein an insulating layer is arranged between the first piezoelectric layer and the capacitor stacking layer; and/or
a mass loading layer located in the first overlapping region is arranged between the first piezoelectric layer and the second electrode layer; and/or
a second piezoelectric layer is arranged between the substrate and the first electrode layer.

8. The resonator according to claim 1, wherein a first cavity and a second cavity are further arranged between the substrate and the first piezoelectric layer; the first cavity is at least partially located within the first overlapping region; and the second cavity is located directly below the capacitor stacking layer.

9. The resonator according to claim 8, wherein an oxide layer is filled within the second cavity.

10. A preparation method for a resonator, wherein the method comprises:
sequentially forming a stacked second piezoelectric layer, a first electrode layer, and a first piezoelectric layer on a substrate;
forming a mass loading layer on the first piezoelectric layer;
forming a second electrode layer on the mass loading layer and forming a lower electrode on the first piezoelectric layer, wherein the second electrode layer and the lower electrode are arranged at intervals;
forming a dielectric layer on the lower electrode;
forming at least one upper electrode on the dielectric layer, wherein the lower electrode, the dielectric layer, and the at least one upper electrode form a capacitor stacking layer; and
forming a passivation layer on the second electrode layer, wherein the passivation layer extends above the capacitor stacking layer.
